(19) United States
(12) Patent Application Publication
(10) Pub. No.: US 2009/0166662 A1
(43) Pub. Date: Jul. 2, 2009

(54) III-Nitride Semiconductor Light Emitting Device

(75) Inventors: Chang Tae Kim, Gyunggi-do (KR); Gi Yeon Nam, Gyunggi-do (KR)

Correspondence Address: HARNESS, DICKEY, & PIERCE, P.L.C, 7700 Bonhomme, Suite 400, ST. LOUIS, MO, 63105, US

(73) Assignee: EPIVALLEY CO., LTD., Gyeonggi (KR)

(21) Appl. No.: 12/195,674

(22) Filed: Aug. 21, 2008

(30) Foreign Application Priority Data
Dec. 31, 2007 (KR) 10-2007-0142014

(51) Int. Cl. H01L 33/00

(52) U.S. Cl. 257/99; 257/E33.062

(57) ABSTRACT

The present disclosure relates to a III-nitride semiconductor light emitting device comprising: a plurality of III-nitride semiconductor layers with an active layer generating light by recombination of holes and electrons; and a branch electrode provided with an arm extended from the p-side bonding pad toward the n-side electrode and two fingers branched off toward the n-side electrode from the arm.

### CROSS-REFERENCE TO RELATED APPLICATIONS

This application claims the benefit of Korean Patent Application No. 10-2007-0142014 filed Dec. 31, 2007. The entire disclosure of the above application is hereby incorporated by reference.

### FIELD

The present disclosure relates to a III-nitride semiconductor light emitting device, and more particularly, to a III-nitride semiconductor light emitting device which provides an electrode for improving current spreading. The III-nitride semiconductor light emitting device means a light emitting device such as a light emitting diode including a compound semiconductor layer composed of Al₍ₓ₎Ga_{(y)}In_{(1-x-y)}N (0≦x≦1, 0≦y≦1, 0≦x+y≦1), and may further include a material composed of other group elements, such as SiC, SiN, SiCN and CN, and a semiconductor layer made of such materials.

### BACKGROUND

This section provides background information related to the present disclosure which is not necessarily prior art.

FIG. 1 is a view illustrating one example of a conventional III-nitride semiconductor light emitting device. The III-nitride semiconductor light emitting device includes a substrate 10, a buffer layer 20 epitaxially grown on the substrate 10, an n-type nitride semiconductor layer 30 epitaxially grown on the buffer layer 20, an active layer 40 epitaxially grown on the n-type nitride semiconductor layer 30, a p-type nitride semiconductor layer 50 epitaxially grown on the active layer 40, a p-side electrode 60 formed on the p-type nitride semiconductor layer 50, a p-side bonding pad 70 formed on the p-side electrode 60, an n-side electrode 80 formed on the n-type nitride semiconductor layer 30 exposed by etching the p-type nitride semiconductor layer 50 and the active layer 40, and a protective film 90.

In the case of the substrate 10, a GaN substrate can be used as a homo-substrate, and a sapphire substrate, a SiC substrate or a Si substrate can be used as a hetero-substrate. However, any type of substrate that can grow a nitride semiconductor layer thereon can be employed. In the case that the SiC substrate is used, the n-side electrode 80 can be formed on the side of the SiC substrate.

The nitride semiconductor layers epitaxially grown on the substrate 10 are grown usually by metal organic chemical vapor deposition (MOCVD).

The buffer layer 20 serves to overcome differences in lattice constant and thermal expansion coefficient between the hetero-substrate 10 and the nitride semiconductor layers. U.S. Pat. No. 5,122,845 mentions a technique of growing an AIN buffer layer with a thickness of 100 to 500 Å on a sapphire substrate at 380 to 800° C. In addition, U.S. Pat. No. 5,290,393 mentions a technique of growing an Al₍ₓ₎Ga₍₁₋ₓ₎N (0≦x<1) buffer layer with a thickness of 10 to 5000 Å on a sapphire substrate at 200 to 900° C. Moreover, PCT Publication No. WO/05/053042 mentions a technique of growing a SiC buffer layer (seed layer) at 600 to 990° C., and growing an In₍ₓ₎Ga₍₁₋ₓ₎N (0<x≦1) thereon. Preferably, it is provided with an undoped GaN layer with a thickness of 1 to several μm on the AIN buffer layer, Al₍ₓ₎Ga₍₁₋ₓ₎N (0≦x<1) buffer layer or SiC/In₍ₓ₎Ga₍₁₋ₓ₎N (0<x≦1) layer.

In the n-type nitride semiconductor layer 30, at least the n-side electrode 80 formed region (n-type contact layer) is doped with a dopant. Preferably, the n-type contact layer is made of GaN and doped with Si. U.S. Pat. No. 5,733,796 mentions a technique of doping an n-type contact layer at a target doping concentration by adjusting the mixture ratio of Si and other source materials.

The active layer 40 generates light quanta (light) by recombination of electrons and holes. Normally, the active layer 40 contains In₍ₓ₎Ga₍₁₋ₓ₎N (0<x≦1) and has single or multi-quantum well layers. PCT Publication No. WO/02/021121 mentions a technique of doping some portions of a plurality of quantum well layers and barrier layers.

The p-type nitride semiconductor layer 50 is doped with an appropriate dopant such as Mg, and has p-type conductivity by an activation process. U.S. Pat. No. 5,247,533 mentions a technique of activating a p-type nitride semiconductor layer by electron beam irradiation. Moreover, U.S. Pat. No. 5,306,662 mentions a technique of activating a p-type nitride semiconductor layer by annealing over 400° C. PCT Publication No. WO/05/022655 mentions a technique of endowing a p-type nitride semiconductor layer with p-type conductivity without an activation process, by using ammonia and a hydrazine-based source material together as a nitrogen precursor for growing the p-type nitride semiconductor layer.

The p-side electrode 60 is provided to facilitate current supply to the p-type nitride semiconductor layer 50. U.S. Pat. No. 5,563,422 mentions a technique associated with a light transmitting electrode composed of Ni and Au and formed almost on the entire surface of the p-type nitride semiconductor layer 50 and in ohmic-contact with the p-type nitride semiconductor layer 50. In addition, U.S. Pat. No. 6,515,306 mentions a technique of forming an n-type superlattice layer on a p-type nitride semiconductor layer, and forming a light transmitting electrode made of ITO thereon.

Meanwhile, the light transmitting electrode 60 can be formed thick not to transmit but to reflect light toward the substrate 10. This technique is called a flip chip technique. U.S. Pat. No. 6,194,743 mentions a technique associated with an electrode structure including an Ag layer with a thickness over 20 nm, a diffusion barrier layer covering the Ag layer, and a bonding layer containing Au and Al, and covering the diffusion barrier layer.

The p-side bonding pad 70 and the n-side electrode 80 are provided for current supply and external wire bonding. U.S. Pat. No. 5,563,422 mentions a technique of forming an n-side electrode with Ti and Al.

The protection film 90 can be made of SiO₂, and may be omitted.

In the meantime, the n-type nitride semiconductor layer 30 or the p-type nitride semiconductor layer 50 can be constructed as single or plural layers. Recently, a technology of manufacturing vertical light emitting devices is introduced by separating the substrate 10 from the nitride semiconductor layers using laser technique or wet etching.

FIG. 2 is a view illustrating one example of a light emitting device described in U.S. Pat. No. 6,307,218, particularly, various finger electrodes 14a and 14b provided to smoothly supply current in a III-nitride semiconductor light emitting device which has a large area or needs to change the electrode arrangement according to the specification of a product.

However, when the number of the finger electrodes 14a and 14b provided to smoothly supply current increases, a light emission area of the III-nitride semiconductor light emitting device decreases. In addition, the finger electrodes 14a and 14b reflect photon (light) generated in the light emitting device to thereby reduce external quantum efficiency.

FIG. 3 is a view illustrating one example of a light emitting device described in PCT Publication No. WO2004/061509, particularly, a III-nitride semiconductor light emitting device with a rough surface 11 formed on an n-type nitride semiconductor layer 33 to improve external quantum efficiency.

However, since a finger electrode 22 extended from an n-side electrode is formed on the n-type nitride semiconductor layer 33, the finger electrode 22 reduces an area of the rough surface 11 formed on the n-type nitride semiconductor layer 33, thereby degrading external quantum efficiency.

### SUMMARY

This section provides a general summary of the disclosure, and is not a comprehensive disclosure of its full scope or all of its features.

In an embodiment of the present disclosure, a III-nitride semiconductor light emitting device comprises a substrate; a buffer layer epitaxially grown over the substrate; an n-type nitride semiconductor layer epitaxially grown over the buffer layer; an active layer epitaxially grown over the n-type nitride semiconductor layer; a p-type nitride semiconductor layer epitaxially grown over the active layer; a p-side electrode formed over the p-type nitride semiconductor layer; an n-side electrode formed on the n-type nitride semiconductor layer exposed by etching the p-type nitride semiconductor layer and the active layer; a p-side bonding pad electrically contacted with the p-side electrode; and a branch electrode provided with an arm extended from the p-side bonding pad toward the n-side electrode and two fingers branched off toward the n-side electrode from the arm.

Further areas of applicability will become apparent from the description provided herein. The description and specific examples in this summary are intended for purposes of illustration only and are not intended to limit the scope of the present disclosure.

### DESCRIPTION OF DRAWINGS

FIG. 1 is a view illustrating one example of a conventional III-nitride semiconductor light emitting device.

FIG. 2 is a view illustrating one example of a light emitting device described in U.S. Pat. No. 6,307,218.

FIG. 3 is a view illustrating one example of a light emitting device described in PCT Publication No. WO2004/061509.

FIG. 4 and FIG. 5 are views illustrating an III-nitride semiconductor light emitting device according to embodiments of the present disclosure.

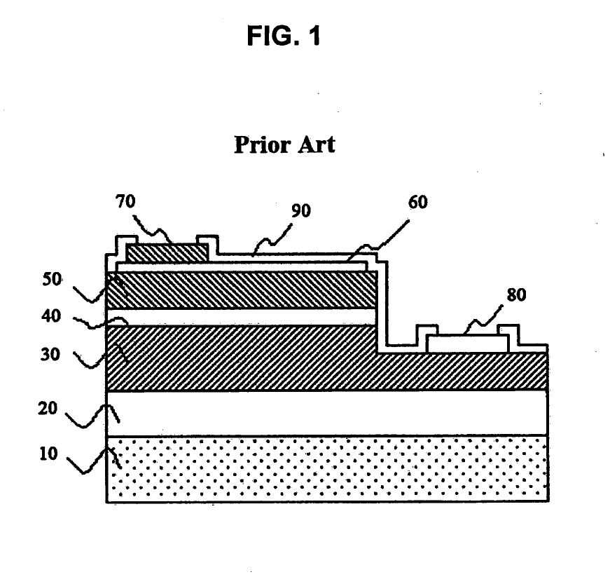

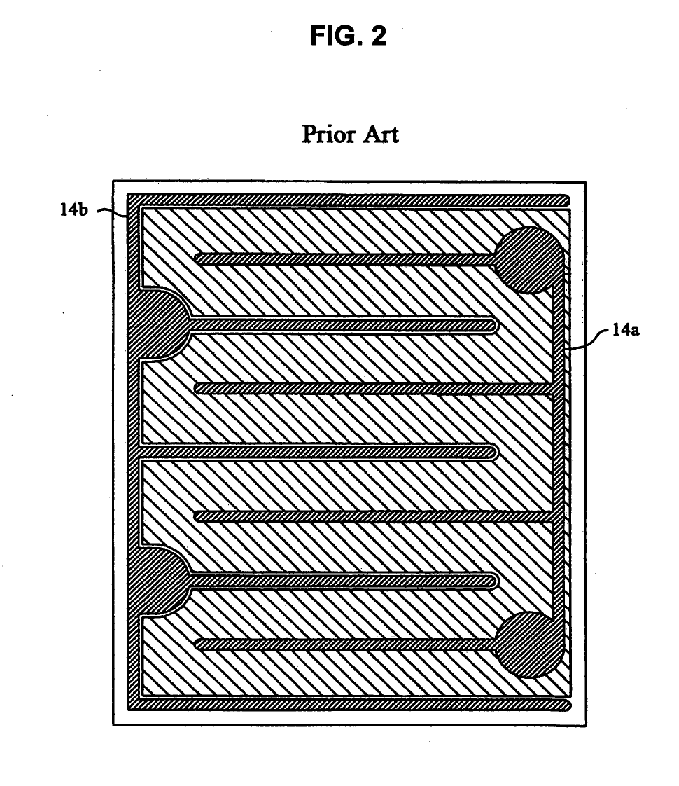

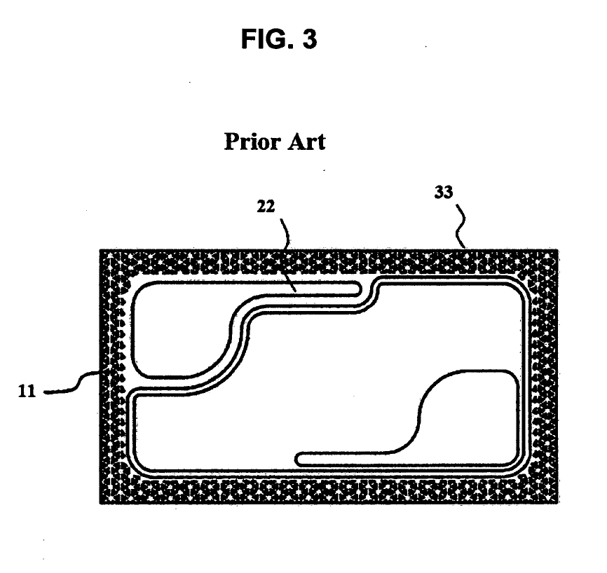

### DETAILED DESCRIPTION

The present disclosure is to provide a III-nitride semiconductor light emitting device which can improve an electrical characteristic by facilitating current spreading through a branch electrode, improve an optical characteristic by reducing light reflection by the branch electrode, and improve external quantum efficiency by increasing an area of a rough surface on a nitride semiconductor layer.

In the present disclosure, there is provided a III-nitride semiconductor light emitting device which includes: a substrate; a buffer layer epitaxially grown over the substrate; an n-type nitride semiconductor layer epitaxially grown over the buffer layer; an active layer epitaxially grown over the n-type nitride semiconductor layer; a p-type nitride semiconductor layer epitaxially grown over the active layer; a p-side electrode formed over the p-type nitride semiconductor layer; an n-side electrode formed over the n-type nitride semiconductor layer exposed by etching the p-type nitride semiconductor layer and the active layer; a p-side bonding pad formed over the p-side electrode; and a branch electrode provided with an arm extended from the p-side bonding pad toward the n-side electrode and two fingers branched off toward the n-side electrode from the arm.

In another aspect of the present disclosure, the two fingers of the branch electrode are formed to surround the n-side electrode at a predetermined distance from the n-side electrode.

In another aspect of the present disclosure, the light emitting device has an rectangular shape with a long side and a short side, and the arm is extended along the long side.

In another aspect of the present disclosure, a portion of the n-type semiconductor layer exposed by etching and a rough surface is formed on the exposed portion of the n-type semiconductor layer.

In another aspect of the present disclosure, the two fingers are branched off in the center between the p-side electrode and the n-side electrode.

According to the present disclosure, the III-nitride semiconductor light emitting device can improve an electrical characteristic by facilitating current spreading through the branch electrode, improve an optical characteristic by reducing light reflection by the branch electrode, and improve external quantum efficiency by increasing the area of the rough surface on the nitride semiconductor layer.

Example embodiments will now be described more fully with reference to the accompanying drawings.

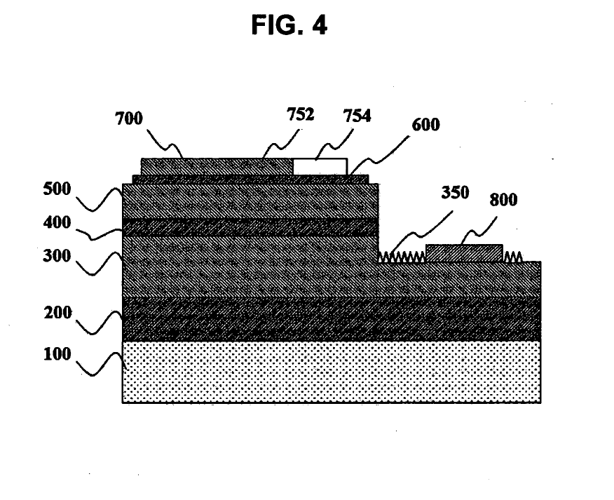

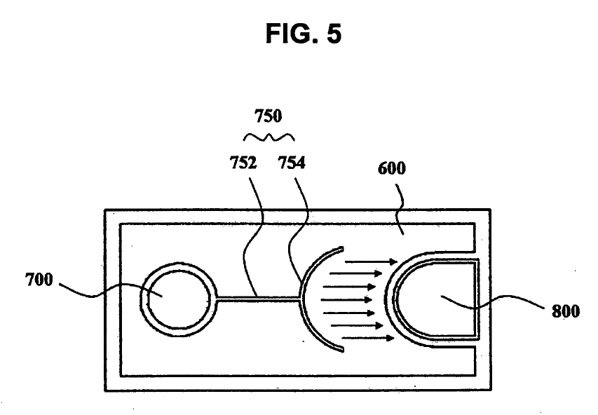

FIG. 4 and FIG. 5 are views illustrating a III-nitride semiconductor light emitting device according to the present disclosure. The III-nitride semiconductor light emitting device includes a substrate 100, a buffer layer 200 epitaxially grown on the substrate 100, an n-type nitride semiconductor layer 300 epitaxially grown on the buffer layer 200, an active layer 400 epitaxially grown on the n-type nitride semiconductor layer 300, a p-type nitride semiconductor layer 500 epitaxially grown on the active layer 400, a p-side electrode 600 formed on the p-type nitride semiconductor layer 500, a p-side bonding pad 700 formed on the p-side electrode 600, an n-side electrode 800 formed on the n-type nitride semiconductor layer 300 exposed by etching the p-type nitride semiconductor layer 500 and the active layer 400, and a branch electrode 750 connected to the p-side bonding pad 700.

The branch electrode 750 includes an arm 752 formed to extend from the p-side bonding pad 700 toward the n-side electrode 800, and two fingers 754 branched off from an end of the arm 752 toward the n-side electrode 800. Here, the branch electrode 750 can be formed on the p-side electrode 600 with the p-side bonding pad 700.

Preferably, the arm 752 extends from the p-side bonding pad 700 to the center between the p-side bonding pad 700 and the n-side electrode 800. In addition, the two fingers 754 are preferably formed in the same contour as that of the n-side electrode 800 to surround the n-side electrode 800 at a predetermined distance from the n-side electrode 800. Accordingly, current is uniformly spread between the p-side bonding pad 700 and the n-side electrode 800, while current is uniformly spread to either side of the light emitting device through the arm 752, thus the present disclosure is particularly suitable for an elongated light emitting device or an rectangular light emitting device.

Here, if the two fingers 754 are formed adjacent to the p-side bonding pad 700 from the center between the p-side bonding pad 700 and the n-side electrode 800, since the two fingers 754 are distant from the n-side electrode 800, a forward bias voltage V_{f} may increase. On the contrary, if the two fingers 754 are formed adjacent to the n-side electrode 800 from the center between the p-side bonding pad 700 and the n-side electrode 800, since current can be concentrated between the two fingers 754 and the n-side electrode 800, a light emission area may be undesirably concentrated between the two fingers 754 and the n-side electrode 800, to thereby reduce quantum efficiency. However, it should be noted to the skilled person in the art that there is no need that the two fingers 754 have to be centered and that the position can be adjusted under above-described restrictions on V_{f} and emission concentration.

Preferably, the n-type nitride semiconductor layer 300 has a rough surface 350 except the n-side electrode 800 as shown in FIG. 4. Generally, some of photon (light) generated in the light emitting device cannot be emitted to the outside of the light emitting device due to total reflection. The rough surface 350 solves this problem and increases external quantum efficiency. Particularly, since the branch electrode 750 provided in the present disclosure is formed merely to the p-side bonding pad 700 side, the n-type semiconductor layer 300 can secure a sufficient area of the rough surface 350 to thereby improve external quantum efficiency.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

What is claimed:

1. A III-nitride semiconductor light emitting device comprising:
a substrate;
a buffer layer epitaxially grown over the substrate;
an n-type nitride semiconductor layer epitaxially grown over the buffer layer;
an active layer epitaxially grown over the n-type nitride semiconductor layer;
a p-type nitride semiconductor layer epitaxially grown over the active layer;
a p-side electrode formed over the p-type nitride semiconductor layer;
an n-side electrode formed on the n-type nitride semiconductor layer exposed by etching the p-type nitride semiconductor layer and the active layer;
a p-side bonding pad electrically contacted with the p-side electrode; and
a branch electrode provided with an arm extended from the p-side bonding pad toward the n-side electrode and two fingers branched off toward the n-side electrode from the arm.

2. The III-nitride semiconductor light emitting device of claim 1,
wherein the two fingers of the branch electrode are formed to surround the n-side electrode at a predetermined distance from the n-side electrode.

3. The III-nitride semiconductor light emitting device of claim 1,
wherein the light emitting device has an rectangular shape with a long side and a short side, and the arm is extended along the long side.

4. The III-nitride semiconductor light emitting device of claim 1, wherein a portion of the n-type semiconductor layer exposed by etching and a rough surface is formed on the exposed portion of the n-type semiconductor layer.

5. The III-nitride semiconductor light emitting device of claim 1,
wherein the two fingers are branched off in the center between the p-side electrode and the n-side electrode.
